(19) United States
(12) Patent Application Publication
(10) Pub. No.: US 2022/0336188 A1
(43) Pub. Date: Oct. 20, 2022

(54) PLASMA TREATMENT SYSTEM AND PLASMA TREATMENT METHOD

(71) Applicant: SINGULUS TECHNOLOGIES AG, Kahl am Main (DE)

(72) Inventors: Frank May, Frankfurt (DE); Bernhard Cord, Alzenau (DE); Simon Hübner, Seligenstadt (DE); Peter Wohlfart, Kahl am Main (DE)

(21) Appl. No.: 17/640,782

(22) PCT Filed: Aug. 11, 2020
(86) PCT No.: PCT/EP2020/072492

§ 371 Date: Mar. 4, 2022

(30) Foreign Application Priority Data
Sep. 6, 2019 (DE) 10 2019 213 591.9

(51) Int. Cl. H01J 37/32

(52) U.S. Cl. CPC H01J 37/321; H01J 37/3244

(57) ABSTRACT

A treatment system (100) comprises a process chamber (101) for dynamic or static treatment of at least one substrate. An inductively coupled plasma source, ICP source (120, 120′), comprises at least one inductor (130a, 130b) extending along the longitudinal direction of the ICP source (120, 120′), a gas supply device (141, 142) for one or a plurality of process gases, and a gas directing arrangement (150) disposed in the process chamber (101), said gas directing arrangement (150) extending along the longitudinal direction of the ICP source (120, 120′) and partially surrounding the at least one inductor (130a, 130b).

### TECHNICAL FIELD

The invention relates to treatment systems and plasma treatment methods in which an inductively coupled plasma (ICP) is excited with an ICP source. The invention relates in particular to systems and methods which allow coating, etching, cleaning or other treatments of a substrate to be performed in a continuous treatment system or batch-type system.

### BACKGROUND

Treatment systems for treating a substrate using an inductively coupled plasma (ICP) are known. A treatment using ICP sources for plasma excitation offers several advantages. For instance, an ICP source provides an H-mode with high electron density that is beneficial for efficient treatment.

Exemplary systems and plasma sources for generating an ICP are disclosed in WO 2015/036494 A1 and in DE 10 2016 107 400 A1.

Conventional treatment systems and methods for treating a substrate using an ICP still entail several drawbacks. It may be difficult, e.g., to reach high deposition rates, steady operating points even at comparatively high pressures, and/or a high degree of homogeneity during treatment processes. In conventional treatment systems having an ICP source, for instance, parasitic treatment processes may cause significant deposition on inner surfaces of a treatment chamber, in particular in the vicinity of process gas outlets, which results in a high maintenance effort and/or reduces the deposition rate on the substrate. Conventional treatment systems and methods for treating a substrate using an ICP may also have limitations with respect to their scalability. This is in particular the case if the inductor or the inductors of the ICP sources are curved parallel to a substrate plane such as, e.g., in a planar antenna array with a helical inductor.

### BRIEF DESCRIPTION OF THE INVENTION

It is an object of the invention to provide an improved treatment system and an improved method for treating a substrate using an inductively coupled plasma (ICP). It is in particular an object of the invention to provide a treatment system and a method which reduce parasitic deposition processes, allow for high deposition rates and enable operation of the treatment system even at higher pressures within the process chamber as well as with larger substrate widths and higher throughput.

According to the invention, a treatment system and a plasma treatment method comprising the features recited in the independent claims are provided. The dependent claims define exemplary embodiments.

A treatment system according to the invention comprises a process chamber for dynamic or static treatment of at least one substrate. The treatment system comprises an inductively coupled plasma source (ICP source) having a longitudinal direction. The ICP source comprises at least one inductor which extends in the longitudinal direction of the ICP source, a gas supply device for one or a plurality of process gases having at least one outlet opening, the gas supply device being configured to supply the process gas or the process gases at a plurality of positions in the longitudinal direction of the ICP source, and a gas directing arrangement disposed in the process chamber. The gas directing arrangement extends in the longitudinal direction of the ICP source and partly surrounds the at least one inductor.

In the treatment system according to the invention, a linear ICP source is provided with a gas directing arrangement partially surrounding the at least one inductor. A directed flow of process gas with higher velocity towards a substrate may thus be created. The risk of parasitic deposition processes, e.g., in an environment of the process gas inlets, may be reduced by the directed flow with high flow velocity. When used in a deposition system, a high deposition rate may be achieved. The ICP source is scalable along its longitudinal direction such that a high homogeneity of treatment may be achieved also across larger substrate widths.

Each inductor may comprise one tubular conductor.

Each inductor may be surrounded by one cylindrical insulator, e.g., a fused silica cylinder.

Each inductor may comprise a cooling fluid flowing through or around it for cooling.

Each inductor may be a linear inductor.

The gas directing arrangement may comprise one or a plurality of gas directing plates.

The gas directing arrangement may comprise a gas hood covering the at least one inductor and the at least one outlet opening.

The gas hood may comprise an outlet whose width B₁ perpendicular to the longitudinal direction of the ICP source is at most 300 mm, in particular at most 200 mm, in particular at most 150 mm, in particular at most 130 mm.

The gas hood may have a further width B₂ perpendicular to the longitudinal direction of the ICP source on its upper side remote from the outlet, which is smaller than the width B₁ of the outlet.

The gas hood may have an inner width decreasing in the vertical direction of the gas hood, i.e., the side facing away from the substrate.

The gas hood may have a height H in a center plane of the gas directing arrangement and an outlet having a width B₁ perpendicular to the longitudinal direction of the ICP source. A ratio of the width B₁ of the outlet to the height of the gas directing arrangement, B₁/H, may be less than 1.0, in particular less than 0.7, in particular less than 0.6, in particular less than 0.5.

A narrow configuration of the gas hood in the direction transverse to the longitudinal direction of the ICP source may efficiently reduce the risk of parasitic deposition processes and/or achieve a high deposition rate.

The gas supply device may comprise at least one gas supply tube extending parallel to the at least one inductor in the gas hood along the longitudinal direction of the ICP source.

The outlet opening of the gas supply device and the at least one inductor may be spaced from one another along a center plane of the gas supply device.

The outlet opening of a gas supply tube may be positioned above the at least one inductor, i.e., spaced further away from the outlet of the gas hood.

The at least one inductor may comprise a first inductor and a second inductor.

The first inductor may be electrically connected in series with the second inductor, thus creating an inductor loop.

The first inductor may be electrically connected in parallel with the second inductor.

The first inductor and the second inductor may be disposed in a center plane of the gas directing arrangement.

By means of such an arrangement of a plurality of inductors, the ICP source may be constructed to have a small width measured perpendicularly to the longitudinal direction of the ICP source, thus efficiently reducing the risk of parasitic deposition processes and/or achieving a high deposition rate.

The ICP source may comprise a generator coupled with the at least one inductor.

The generator may be electrically or electromagnetically connected with the at least one inductor.

The ICP source may comprise an matching circuit which may include, e.g., coils and/or capacitors but is not limited thereto. The matching circuit may be connected between the generator and the at least one inductor.

The generator may be configured to operate the ICP source in H-mode.

The generator may comprise a HF or RF generator.

The generator may be configured to generate electric waves having wavelengths of at least 5 m, preferably at least 10 m, in the at least one inductor.

By means of such a configuration of the ICP source, a high homogeneity of treatment may be achieved even if the ICP source extends over more than 1,000 mm in its longitudinal direction.

The ICP source may be configured to create a plasma having an electron density of at least 10¹⁶/m³, advantageously of at least 10¹⁷/m³.

The ICP source may be configured for operation at a pressure within a range of 0.1 to 1,000 Pa, in particular of 0.1 to 500 Pa, in particular of 0.1 Pa to 250 Pa, in particular of 0.1 Pa to 200 Pa, in particular of 1 Pa to 100 Pa, in particular of 10 Pa to 100 Pa in the process chamber.

The treatment system may comprise a gas distributor for process gas, wherein the gas directing arrangement comprises a shield for the gas distributor.

The shield may comprise an outlet slit extending along the gas directing arrangement or a series of apertures disposed along the longitudinal direction of the ICP source.

The outlet slit or the apertures may have a width of at most 40 mm, in particular of at most 25 mm, in particular of at most 10 mm.

The gas distributor may comprise a plurality of outlet openings with an outlet opening diameter, wherein a ratio of the outlet opening diameter to a diameter of the gas distributor may be at most 0.5, in particular at most 0.1.

The gas directing arrangement suppresses parasitic coatings in the immediate vicinity of the outlet openings. The velocity of a precursor gas generated by the gas directing arrangement counteracts, e.g., back diffusion of the excited precursor in the direction of the outlet openings, thus reducing parasitic coating processes in the immediate vicinity of the outlet openings of the gas distributor.

The at least one inductor may have a length of at least 1,000 mm, in particular of at least 1,200 mm, in particular of at least 1,400 mm along the longitudinal direction of the ICP source.

The treatment system may be a continuous treatment system for dynamically coating substrates, with the substrates being moved past the ICP source in the treatment system.

The longitudinal direction of the ICP source may extend perpendicular to a transport direction of the substrate in the continuous treatment system.

The treatment system may be designed for static treatment of the substrates with the ICP source, e.g., it may be a batch-type system.

The treatment system may be a coating system. The coating system may be configured for depositing aluminum oxide (AlOx) or silicon nitride (SiNx) without being limited thereto. For instance, dielectric layers (oxides, nitrides and/or oxynitrides), intrinsic and doped semiconductive layers, e.g., a-Si, n-/p-doped Si and/or transparent conductive oxides (TCO) may be deposited.

The treatment system may be configured for etching the substrate. For this purpose, chemical etching or physical etching with bias voltage may be performed on the substrate or the ICP source.

The treatment system may be configured for cleaning the substrate.

The treatment system may be configured to oxidize a surface of the at least one substrate.

The treatment system may be configured to generate oxides, nitrides, and/or oxynitrides.

The treatment system may be configured to functionalize surfaces. For example, the treatment system may be configured to functionalize a surface with hydroxyl groups. The treatment system may be configured to create hydroxyl groups on the surface by generating a plasma with oxygen and/or water.

The treatment system may be configured to perform a cleaning process.

A plasma treatment method according to the invention for statically or dynamically treating substrates using a treatment system comprises the following steps: positioning at least one substrate in a process chamber of the treatment system; exciting an inductively coupled plasma, ICP using an ICP source which comprises at least one inductor extending along a longitudinal direction of the ICP source, a gas supply device, and a gas directing arrangement disposed in the process chamber, said gas directing arrangement extending along a longitudinal direction of the ICP source and partially surrounding the at least one inductor; and supplying a process gas or a plurality of process gases with the gas supply device at a plurality of positions along the longitudinal direction of the ICP source.

The effects achieved with the plasma treatment method according to the invention correspond to the effects described with respect to the treatment system.

The treatment system used with the plasma treatment method may be a treatment system according to any of the exemplary embodiments disclosed herein.

The plasma treatment method may be a coating method. In this context, AlOx or SiNx may be deposited without the method being limited thereto.

In the plasma treatment method, dynamic layer deposition may take place at a rate that is at least 70 nm m/min for a deposition of SiNx or at least 8 nm m/min for a deposition of AlOx.

In the plasma treatment method, layer deposition may take place with a deviation of less than ±3%, in particular less than ±2% along the longitudinal direction of the ICP source.

The plasma treatment method may comprise etching of the substrate. For this purpose, chemical etching or physical etching with bias may be performed on the substrate.

The plasma treatment method may comprise cleaning or a surface treatment (e.g., oxidation and/or functionalization) of the substrate.

The plasma treatment method may comprise generating oxides, nitrides, and/or oxynitrides. Intrinsic and doped semi-conductive layers, e.g., a-Si, n-/p-doped Si and/or transparent conductive oxides (TCO) may be deposited.

Several effects and advantages can be achieved by the treatment system according to the invention and the treatment method according to the invention.

For instance, the use of an ICP source allows for operating the ICP source in H-mode, i.e., with high plasma density and high conductivity of the plasma, without necessarily requiring magnets (permanent magnets and/or electromagnets) for creating plasma confinement. The deposition of layers with high rates and homogeneity is facilitated. The use of the gas directing arrangement causes initiation and operation of the H-mode also at high pressures and with high stability, which may also increase the deposition rate.

The configuration of the ICP source according to the invention allows the plasma volume to be reduced by the gas directing arrangement disposed inside the process chamber, whereby at a given energy coupling rate the electron density may be increased, and the H-mode may be stably maintained even at higher pressures. Thus, high and homogeneous deposition rates may be achieved. A configuration of the gas directing arrangement that is narrow transverse to the longitudinal direction of the ICP source increases the gas velocity in the direction of the substrate at a given gas flow rate. This gas flow counteracts the diffusion of a precursor into the upper area of the ICP source. Thus, a larger portion of the precursor is directed onto the substrate, which results in a high deposition rate. Parasitic depositions in the area of the ICP source are reduced. In this way, the deposition rate on the substrate may be increased and the maintenance effort of the treatment system may be reduced.

### BRIEF DESCRIPTION OF THE DRAWINGS

In the following, exemplary embodiments of the invention are described in detail with reference to the figures, in which identical reference signs indicate identical or similar elements.

FIG. 1 is a schematic illustration of a treatment system according to an exemplary embodiment in a sectional view.

FIG. 2 is a schematic illustration of an ICP source in a sectional view, wherein a drawing plane is perpendicular to a longitudinal direction of the ICP source.

FIG. 3 is a schematic illustration of an ICP source in a sectional view, wherein a drawing plane is perpendicular to a longitudinal direction of the ICP source.

FIG. 4 is a schematic illustration of an ICP source in a sectional view, wherein a drawing plane is perpendicular to a longitudinal direction of the ICP source.

FIG. 5 is a schematic illustration of an arrangement of inductors of an ICP source in a process chamber in a sectional view, wherein a drawing plane is parallel to a longitudinal direction of the ICP source.

FIG. 6 is a schematic illustration of an ICP source in a sectional view, wherein a drawing plane is perpendicular to a longitudinal direction of the ICP source.

FIGS. 7 to 10 show a density of a precursor for ICP sources with different geometries of a gas directing arrangement.

FIGS. 11 to 14 show a gas flow velocity for ICP sources with different geometries of a gas directing arrangement.

### DETAILED DESCRIPTION OF EXEMPLARY EMBODIMENTS

While preferred or advantageous exemplary embodiments are described with respect to the drawings, alternative configurations may be implemented in further exemplary embodiments. For instance, while the figures illustrate an exemplary continuous treatment system, exemplary embodiments may also be deployed in systems for static treatment, in particular batch-type systems.

While, e.g., embodiments are described exemplarily in the context of a coating system for depositing a layer on a substrate, the treatment systems and treatment methods according to embodiments of the invention may also be used for etching, cleaning, functionalization, or for other substrate treatment processes.

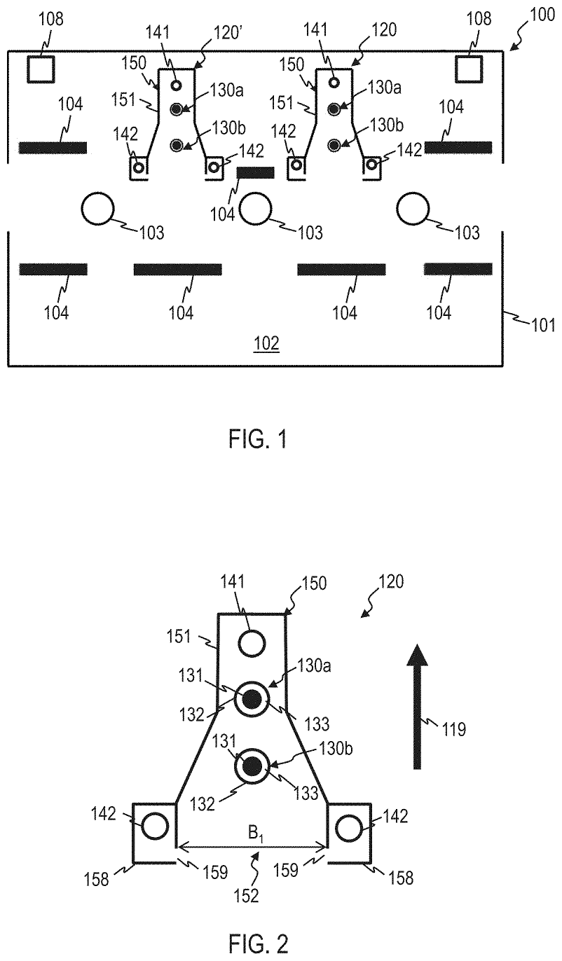

FIG. 1 shows a schematic illustration of a treatment system 100 for treating substrates, in particular for coating, etching, cleaning, and/or functionalizing substrates.

The treatment system 100 comprises a process chamber 101 defining a process space 102. One or a plurality of feed rollers 103 or other transportation units may be provided for moving a substrate. One or a plurality of heating devices 104 and/or shieldings 104 may be disposed at a side or at opposing sides of a substrate plane within the process space 102. A heating device 104 or a plurality of heating devices 104 and/or a shielding 104 or a plurality of shieldings 104 may be disposed, e.g., opposite the ICP sources 120, 120′ and/or between the ICP sources 120, 120′, which are yet to be described below.

The treatment system 100 comprises vacuum pumps 108 in order to evacuate the process chamber 101.

At least one ICP source 120, 120′ is disposed within the process space 102. While two ICP sources 120, 120′ are illustrated exemplarily, only one ICP source or more than two ICP sources may be disposed within the process space 102 in further exemplary embodiments as well.

In a treatment system 100 configured as a continuous treatment system, each one of ICP sources 120, 120′ may be directed such that a longitudinal direction of the ICP source 120, 120′ is transverse, in particular perpendicular, to a transport direction of the substrate.

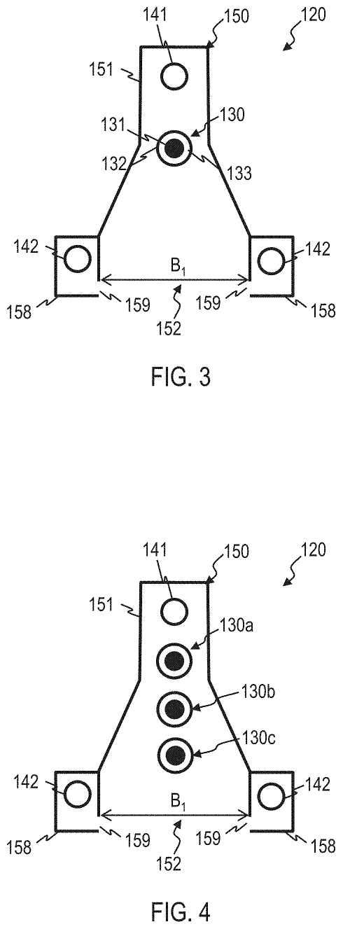

An embodiment of the ICP source which may be deployed in systems and devices according to the invention will be described in more detail in the following. FIGS. 2 to 6 show possible embodiments in detail. If the treatment system 100 comprises a plurality of ICP sources within the process space 102, one, a plurality of, or all of the ICP sources 120, 120′ may have the configuration described in detail herein.

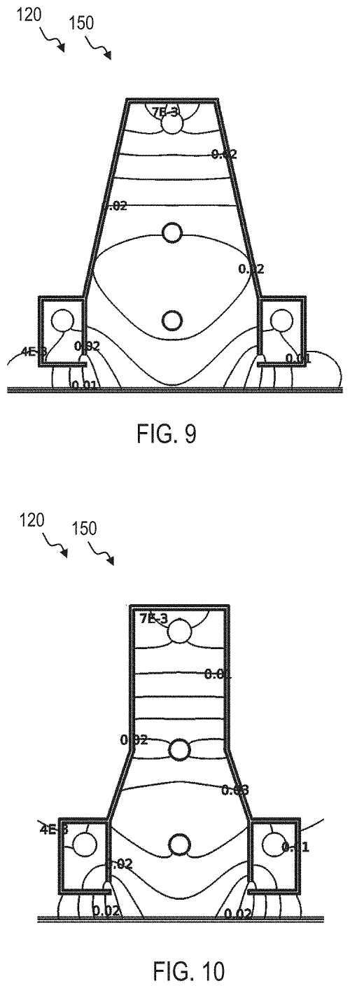

The ICP source 120 has a longitudinal direction. The longitudinal direction extends perpendicularly to the drawing plane of FIGS. 1-5 and 7-14 and parallel to the drawing plane of FIG. 6. With the use of a continuous treatment system, the longitudinal direction of the ICP source 120 may be directed along the substrate width, i.e., perpendicularly to the transport direction in the continuous treatment system.

The ICP source 120 comprises at least one linear inductor 130a, 130b. As illustrated in FIGS. 1 and 2, the ICP source may comprise two linear inductors 130a, 130b. The linear inductors 130a, 130b may extend parallel to each other and respectively parallel to a gas supply tube 141 of a gas supply device.

The inductors 130a, 130b may comprise a conductor 131 which may be shaped in a tubular manner. The inductors 130a, 130b may be surrounded by a hollow cylindrical insulator 132, e.g., a silica tube. A cooling fluid may be disposed in a gap 133 between the hollow cylindrical insulator 132 and the conductor 131 and/or within the tubular conductor 131, said cooling fluid flowing through or around the conductor 131 during operation of the continuous treatment system. The cooling fluid may be circulated.

The ICP source comprises a gas supply device for one or a plurality of process gases, having at least one outlet opening. The gas supply device may comprise a gas supply tube 141 which is arranged within a gas hood 151 that is yet to be described, and which extends linearly parallel to the inductors 130a, 130b. A reaction gas or another process gas may be supplied via the gas supply tube 141. The gas supply device may comprise a gas distributor having one or a plurality of additional tubes 142 via which, e.g., a precursor may be supplied.

The gas supply device may be configured to supply the process gas(es) at several positions along the longitudinal direction of the ICP source 120. For this purpose, one outlet slit or a plurality of outlet apertures may be provided in any one of the gas supply tube 141 and in the additional tubes 142.

According to the invention, the ICP source 120 comprises a gas directing arrangement 150 arranged within the process chamber 101. The gas directing arrangement 150 extends along the longitudinal direction of the ICP source 120. The gas directing arrangement 150 partially surrounds the at least one inductor 130a, 130b and the gas supply tube 141 to limit an area in which plasma is excited in a direction transverse to the longitudinal direction of the ICP source 120.

The gas directing arrangement 150 may comprise one or a plurality of steel sheets. By means of the gas directing arrangement 150, gas is directed from the area around the at least one inductor 130a, 130b, which is operative for exciting the H-mode plasma, in the direction of a substrate via an outlet 152 of the gas directing arrangement 150. The gas directing arrangement 150 may define the flow direction of the gas in the manner of baffle plates or guiding plates and/or spatially confine the plasma in a direction transverse to the longitudinal direction of the ICP source.

The gas directing arrangement 150 may comprise a gas hood 151. The gas hood may extend along the longitudinal direction of the ICP source over and partially around the gas supply tube 141 and the at least one inductor 130a, 130b. The gas hood 151 may have an inner width decreasing in the height direction 119 of the gas hood 151, i.e., from its outlet 152 toward its closed upper end disposed adjacent to the gas supply tube 141. A width B₁ of the outlet may be small, e.g., smaller than a height of the gas directing arrangement 150. Such a narrow configuration of the gas directing arrangement 150 may efficiently define a flow toward the substrate and/or facilitate excitation in the H-mode.

The gas directing arrangement 150 may comprise one or a plurality of shields 158. The shields 158 may extend along the longitudinal direction of the ICP source. The shields 158 may be provided on an outside of the gas hood 151 to surround the additional tubes 142 of the gas supply device and to suppress a flow of a precursor exiting the additional tubes 142 into the interior of the gas hood 151. An outlet slit or cutouts 159 of the shields 158 may direct the process gas exiting the additional tubes 142 toward the outlet 152 where a comparatively high flow velocity within the gas directing arrangement 150 reduces diffusion of said process gas toward the inductors 130a, 130b and the gas supply tube 141. The outlet slit 159 may be a continuous slot parallel to the longitudinal direction of the ICP source 120 or may comprise a series of openings or cutouts along the longitudinal direction of the ICP source 120.

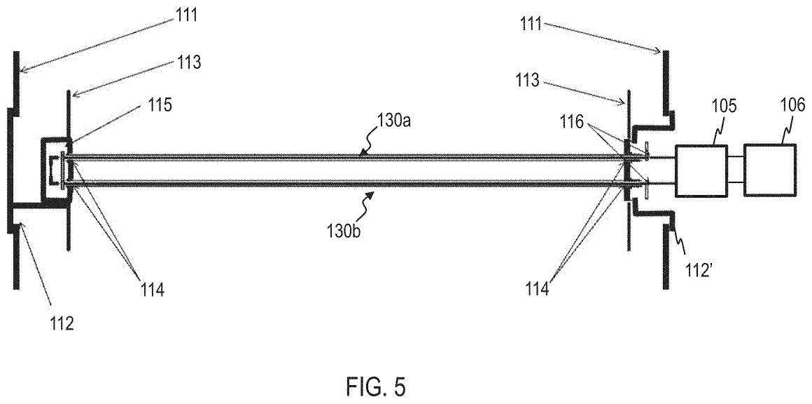

FIG. 3 shows a configuration of the ICP source 120 in which only one linear inductor 130 is arranged in the gas hood 151 of the gas directing arrangement 150. The inductor 130 may comprise a conductor 131 which may be configured in a tubular manner. The inductor 130 may be surrounded by a hollow cylindrical insulator 132, e.g., a silica tube. A cooling fluid may be disposed in a gap 133 between the hollow cylindrical insulator 132 and the conductor 131 and/or within the tubular conductor 131, said cooling fluid flowing through or around the conductor 131 during operation of the continuous treatment system. The cooling fluid may be circulated. Gases or air may be used as a cooling fluid in the gap 133. The tubular conductor 131 may be cooled with liquid media, e.g., water.

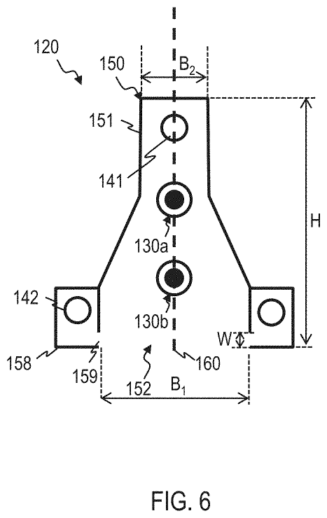

FIG. 4 shows a configuration of the ICP source 120 in which three linear inductors 130a, 130b, 130c are arranged in the gas hood 151 of the gas directing arrangement 150. The inductors 130a, 130b, 130c may comprise a conductor 131 which may be configured in a tubular manner. The inductors 130a, 130b, 130c may be surrounded by a hollow cylindrical insulator 132, e.g., a silica tube. A cooling fluid may be disposed in a gap 133 between the hollow cylindrical insulator 132 and the conductor 131 and/or within the tubular conductor 131, said cooling fluid flowing through or around the conductor 131 during operation of the continuous treatment system. The cooling fluid may be circulated.

When two inductors 130a, 130b or more than two inductors 130a, 130b, 130c are arranged in the gas hood 151 of the gas directing arrangement 150, the inductors 130a, 130b, 130c are preferably arranged in a center plane of the ICP source 120.

The center plane may be a symmetry plane of the ICP source 120 extending parallel to the longitudinal direction of the ICP source 120.

Alternatively or additionally, the center plane 160 of the ICP source 120 may be defined such that it passes through a center line of the outlet 152 of the gas directing arrangement 150 of the ICP source 120 and through a center line of the upper end of the gas directing arrangement 150 of the ICP source 120 that is spaced from the outlet 152 and adjacent to the gas supply tube 141.

Alternatively or additionally, the center plane 160 of the ICP source 120 may be defined by an average velocity vector of the gas exiting the ICP source 120 at the outlet 152, wherein the averaging may be performed over the surface of the outlet 152.

Alternatively or additionally, the center plane 160 of the ICP source 120 may be perpendicular to a substrate plane.

Alternatively or additionally, the center plane 160 of the ICP source 120 may include a center line of the gas supply tube 141 and of at least one, preferably all of the inductors 130, 130a-c.

When two inductors 130a, 130b or more than two inductors 130a, 130b, 130c are arranged in the gas hood 151 of the gas directing arrangement 150, the two inductors 130a, 130b or more than two inductors 130a, 130b, 130c may be connected electrically in series or in parallel.

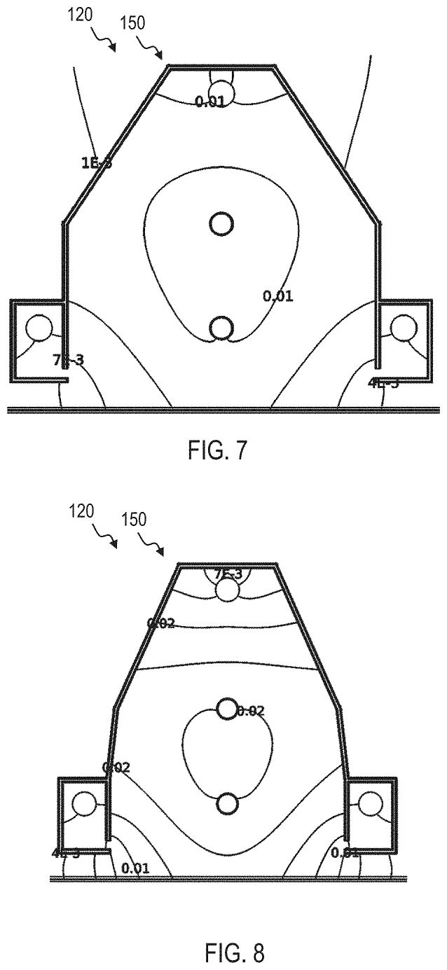

FIG. 5 shows a sectional view of inductors 130a, 130b of an ICP source. The gas directing arrangement 150 is not shown.

The inductors 130a, 130b may be connected to each other electrically and/or fluidically by means of a coupling unit 115. The coupling unit 115 may provide an electrical connection between the inductors 130a, 130b in order to connect them in series and/or couple them to ground. The coupling unit 115 may provide a fluidic connection between the inductors 130a, 130b allowing a cooling fluid to be passed sequentially through or over the first inductor 130a and then through or over the second inductor 130b. Coupling of cooling fluid and/or coupling of electrical power may be accomplished via connections 116.

Shields 113 may be provided at opposite ends of inductors 130a, 130b for terminating the gas directing assembly 150 in the longitudinal direction. The inductors 130a, 130b may be attached to the shields 113 by means of gaskets 114, e.g., by means of squeeze-type gaskets. The gaskets 114 allow the inductors 130a, 130b to be connected with the walls 111 of the process chamber 102 in a vacuum-tight fashion by means of flanges 112, 112′.

Walls 111 of the process chamber 102 may be configured such that they allow the ICP source 120 to be installed from both sides. For instance, the walls 111 may comprise a symmetric opening on opposite sides in order to allow for installation of the inductors 130a, 130b from both sides of the process chamber 102 by means of the flanges 112, 112′.

The ICP source 120 comprises a schematically illustrated generator 106, which may be a high-frequency (HF) or radio-frequency (RF) generator. The HF or RF generator 106 may be electrically or electromagnetically connected with the inductors 130a 130b, e.g., by means of a matching circuit 105. The HF or RF generator 106 may be configured to generate electric waves having wavelengths of at least 5 m, preferably of at least 10 m, in the at least one inductor 130a, 130b. Such a configuration allows a high treatment homogeneity to be attained even when the ICP source extends over more than 1,000 mm in its longitudinal direction.

The HF or RF generator 106 may be configured to generate plasma exhibiting an electron density of at least 10¹⁶/m³, preferably of at least 10¹⁷/m³.

FIG. 6 shows a geometry of the gas directing arrangement 150 which may be used in exemplary embodiments. While two inductors 130a, 130b are illustrated exemplarily, the geometry may also be used with an ICP source having only one inductor or more than two inductors in the gas directing arrangement.

The gas directing arrangement 150 comprises a gas hood 151 having an outlet 152. The gas supply tube 141 and the at least one inductor 130a, 130b are disposed in the gas hood 151. The gas supply tube 141 and the at least one inductor 130a, 130b may be positioned at a center plane 160 of the ICP source 120.

The gas directing arrangement 150 has a height H at the center plane 160 of the gas directing arrangement. The outlet 152 has a width B₁ perpendicular to the longitudinal direction of the ICP source 120. A ratio of the width B₁ of the outlet 152 to the height H, B₁/H, is advantageously less than 1.0. Further advantageously, the ratio of the width B₁ of the outlet 152 to the height H, B₁/H, is less than 0.7, in particular less than 0.6, in particular less than 0.5.

In an exemplary configuration, the width B₁ of the outlet 152 perpendicular to the longitudinal direction of the ICP source is at most 300 mm, in particular at most 200 mm, in particular at most 150 mm, in particular at most 130 mm.

The gas directing arrangement 150 has an upper side far from the outlet 152, which upper side has a width B₂ transverse to the longitudinal direction of the ICP source 120. The width B₂ is less than width B₁ of the outlet 152. Advantageously, B₂/B₁ is less than 1, in particular less than 0.9, in particular less than 0.8.

An inner width of the gas hood 151 may decrease from the outlet 152 to the upper side that is far from the outlet 152, in particular decrease monotonically (but not necessarily strictly monotonically).

The slot 159 or any one of openings 159 of the shield 158 may have a width W which, in exemplary configurations, may be at most 40 mm, in particular at most 25 mm, in particular at most 10 mm.

The inductor 130 or all inductors 130a, 130b, 130c, the gas directing arrangement 150, and the tubes 141, 142 of the gas directing arrangement may extend linearly over a length of at least 1,000 mm, in particular of at least 1,200 mm, in particular of at least 1,400 mm along the longitudinal direction of the ICP source 120.

The inductor 130 or all inductors 130a, 130b, 130c may be configured, e.g., as a coaxial arrangement of a copper tube as inner conductor 131 located in a fused silica glass tube 132. A cooling fluid (e.g., water) may be flowed through the copper tube for cooling. The copper tube may be covered by insulating ceramics. This provides the advantage that the insulation may be very thin, e.g., have a thickness of 0.1 to 2 mm, and/or that that there need be no air gap. As a result, a ratio of the radii of insulator 132 and inner conductor 131 becomes small.

If the plasma becomes the coaxial outer conductor in this arrangement, which is the case in particular for the ICP H-mode, the reduction of the radius ratio of the outer tube 132 to the inner conductor 131 causes the reactance or impedance of the source to be reduced, thus causing the currents to increase and the voltages to be reduced at equal electrical power input. In the case of a current-driven ICP, this increases coupling efficiency.

Further, the source impedance can be made variable along the longitudinal direction of the ICP source 120 by varying the radius of the copper tube, e.g., by trimming, along the longitudinal direction of the ICP source 120 and/or by varying the insulation thickness. Thus, the inhomogeneity of the plasma density, occurring, e.g., on both ends of the ICP source, may be partially or completely compensated for along the longitudinal direction of the ICP source 120. For this purpose, the inductor 130 of the plurality of inductors 130a, 130b, 130c may be configured such that the electrical impedance respectively decreases from the ends of the inductors toward their centers.

Power may be coupled into a plurality of inductors 130a, 130b of an ICP source 130 in different ways:

a) The inductors 130a, 130b may be electrically connected in series. The connection of the conductors of the inductors 130a, 130b to a loop takes place in the coupling unit 115. Said coupling unit may be configured as a closed cavity in which there is preferably atmospheric pressure. Power is provided by the HF or RF generator 106 on the side opposite the coupling unit 115 to only one of the inductors. The power may be coupled into one of the inductors 130a or 130b. The other inductor may be connected to ground directly or via passive electronic components. Alternatively, there is a possibility of using a configuration without termination.

b) The inductors 130a, 130b may be driven in parallel. The conductors of the inductors 130a, 130b are connected on the coupling side. Power is provided by the HF or RF generator 106 on the side opposite the coupling unit 115 to both inductors 130a, 130b. In the coupling unit 115, the conductors may be grounded. Alternatively, the conductors may be grounded by means of passive electronic components, or each of the conductors may be grounded individually by means of own passive electronic components, wherein the passive components may have the same or different impedance. It is possible that the conductors are not connected and not grounded in the coupling unit 115 (without termination).

c) The inductors 130a, 130b may be powered in an opposing manner. For this purpose, an additional conductor isolated from the remaining arrangement and from the plasma may be routed to the coupling unit 115. The inductors may then be either connected to ground independently, or connected to ground via passive electronic components, or be without termination.

d) Only one of the inductors 130a, 130b is driven. Power is provided by the HF or RF generator 106 on the side opposite the coupling unit 115 to only one of the inductors. In the coupling unit 115, the conductor is either connected to ground, or connected to ground via passive electronic components, or be without termination.

The ICP source 120 may be configured such that two different process gases or process gas mixtures can be supplied via the gas supply device. The flow rates of the different process gases or process gas mixtures may be adjustable independently from each other.

A first process gas or a first process gas mixture may be supplied via the gas supply tube 141.

A second process gas different from the first process gas or a second process gas mixture different from the first process gas mixture may be supplied via the additional tubes 142.

The tubes 141, 142 are provided with gas outlet bores for supplying the process gases or process gas mixtures. The gas outlet bores may be arranged having any distances and diameters. For better gas mixing and for protection against occlusion by parasitic coatings, said gas outlet bores may be located on the side of the tubes 141, 142 facing away from the substrate plane and/or on the side facing away from the outlet 152.

The tubes 141, 142 may be interrupted along the longitudinal direction of the ICP source 120 in a gas-tight manner, i.e., segmented. The treatment system may be configured to supply an independent gas flow to the individual segments. A sum of the cross sections of all gas outlet bores per segment is advantageously smaller by a factor of at least three than the cross sectional area 141, 142 of the corresponding tube 141, 142. Thus, it can be ensured that the gas flow of a gas outlet bore is proportional to its cross section and that defined flow rates are created in the process space 102. In order to prevent nonlinear behavior, the gas outlet bores and the gas flow rate are selected such that the velocity of the gas does not approach the speed of sound.

The ICP source 120 may be configured such that a maximum electron density in the generated plasma is 10¹⁴ to 10²¹/m³, in particular 10¹⁴ to 10²⁰/m³, in particular 10¹⁴ to 10¹⁹/m³. The maximum electron density in the generated plasma may be at least 10¹⁶/m³, advantageously at least 10¹²/m³.

The ICP source 120 may be configured such that a gas velocity in the center of the outlet 152 may be from 0.01 to 100 m/s, in particular from 0.01 to 50 m/s, in particular from 0.01 to 10 m/s.

The ICP source 120 may be configured such that a plasma power per length of the ICP source is 0.1 to 100 kW/m, in particular 0.1 to 50 kW/m, in particular 0.1 to 10 kW/m.

The ICP source 120 is designed for operation in a process space, a pressure in the process space being from 0.1 to 1,000 Pa, in particular from 0.1 to 500 Pa, in particular from 0.1 to 250 Pa, in particular from 0.1 to 200 Pa, in particular from 1 Pa to 100 Pa, in particular from 10 Pa to 100 Pa. The pressure within the process space may be determined at any one of the process gas outlet openings in the interior of the process space.

When the treatment system 100 is configured as a coating system, the treatment system may be designed for deposition with a dynamic deposition rate of 0 to 1,000 nm m/min, in particular of 0 to 500 nm m/min, in particular of 0 to 200 nm m/min. These deposition rates are the deposition rates attained in the treatment system 100, which may comprise a plurality of ICP sources.

The use in a process space with a pressure of 0.1 to 1,000 Pa, in particular of 0.1 to 500 Pa, in particular of 0.1 to 250 Pa, in particular of 0.1 to 200 Pa, in particular of 1 Pa to 100 Pa, in particular of 10 Pa to 100 Pa makes the gas flow relevant for process control. Unlike the case of lower pressure present in PVD plants, with increasing pressure transport phenomena become more relevant compared to diffusion. The high reactive gas flow in the substrate direction minimizes diffusion of the precursor gas in the direction opposite to this flow. This favors deposition on the substrate while at the same time reducing unwanted coating of the remaining components of the ICP source 120, such as the inductors 130, 130a-c and/or the tubes 141, 142. By configuring the gas deflection arrangement 150 too narrow, a good deposition rate of the source may be achieved with reduced parasitic coating of the ICP source 120 at the gas feed tube 141 and at the at least one inductor 130, 130a-c.

With the help of the ICP source 120, 120′, dielectric layers (oxides, nitrides, and/or oxynitrides), intrinsic and doped semi-conductive layers, e.g., a-Si, n-/p-doped Si and/or transparent conductive oxides (TCO) may be deposited.

Alternatively or additionally, the treatment system 100 may be designed for etching, cleaning, functionalization, or for another treatment of substrates.

For example, the use of electronegative gases (e.g., F₂, NF₃, Cl₂, O₂) and/or hydrogen as the process gas allows for the ICP source 120, 120′ to be used to chemically etch substrates, e.g., silicon, glass, plastic, metal, and layers of carbon or dielectric materials (e.g., silicon oxide). Alternatively, the ICP source 120, 120′ in combination with a bias voltage on the substrate or the ICP source 120, 120′ may be used to physically etch substrates and surfaces.

In additional embodiments, oxidation, generation of nitrides or oxynitrides with metallic or semiconductive substrates, or coatings using the ICP source 120, 120′ are possible. For this purpose, process gases which comprise oxygen, nitrogen, or compounds containing oxygen and/or nitrogen may be used. The use of the ICP source 120, 120′ allows for deposition of, e.g., tunnel oxide layers (e.g., silicon oxide) onto substrates.

The treatment system 100 may be configured to create hydroxyl groups on a surface by generating plasma under the presence of oxygen and/or water in order to functionalize the surface. In this manner, the surface may be functionalized with hydroxyl groups.

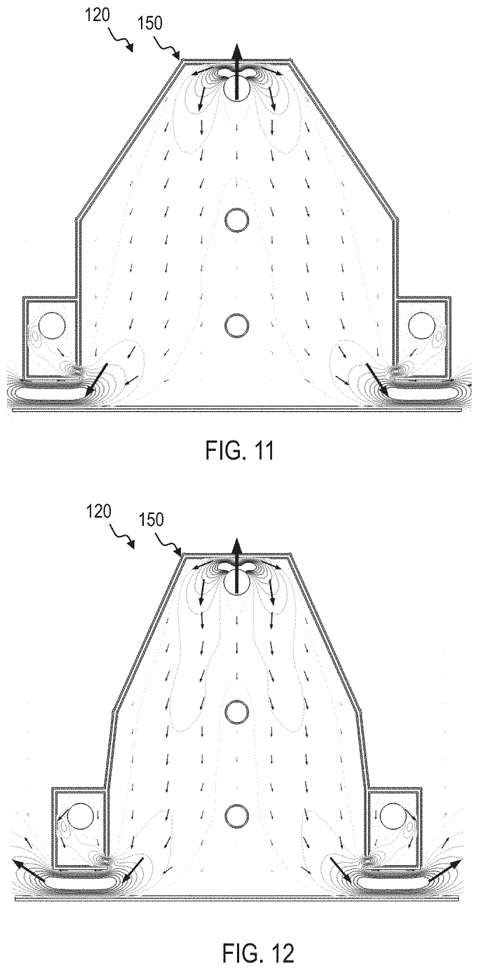

FIG. 7 to FIG. 10 exemplarily show the influence of the width of the gas directing arrangement 150 on a concentration of SiH₃ when SiH₄ is supplied. Here, lines of equal concentration of SiH₃ are shown by level curves indicating the concentration (in arbitrary units, with consistent units being used in FIGS. 7 to 10). In a narrower configuration of the gas directing arrangement, e.g., at a lower ratio of the width B₁ of the outlet 152 to the height H, B₁/H, not only the concentration of SiH₃ may be increased but the maximum of concentration along the height direction 119 of the ICP source 120 may be displaced downward towards the outlet 152. This reduces parasitic coatings in the ICP source 120 and increases the deposition rate on the substrate.

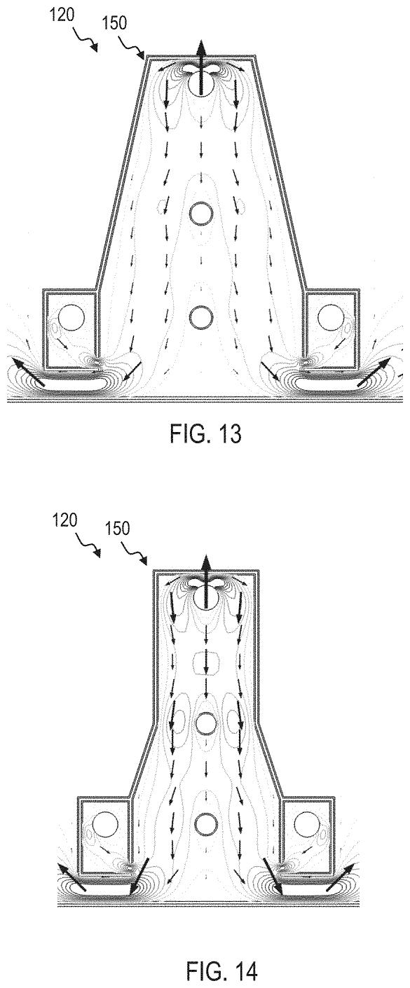

FIG. 11 to FIG. 14 exemplarily show the influence of the width of the gas directing arrangement 150 on a flow velocity of the gas. The flow direction is illustrated as a vector field, wherein the length of each vector represents the velocity. Curves corresponding to the same velocity are additionally illustrated as level curves. In a narrower configuration of the gas directing arrangement, e.g., at a lower ratio of the width B₁ of the outlet 152 to the height H, B₁/H, higher velocities may be reached at the outlet 152 in the direction of the substrate. In this way, parasitic coatings in the ICP source 120 are reduced by reducing diffusion in the direction of the tube 141 and the inductors 130a, 130b, and the deposition rate on the substrate is increased.

Different advantages and effects can be attained by the treatment system and the treatment method using the ICP source 120.

When used in a coating system, the ICP source enables a high deposition rate to be attained, which may be at least 70 nm m/min for depositing SiNx or at least 8 mm m/min for depositing AlOx.

For depositing layers of determined thicknesses, fewer sources may be used in a system for a given throughput, and/or the possible throughput of a coating system may be increased for a given number of coating sources. The problem of high system costs may thus be reduced.

Stable working points become feasible also at higher pressures in the process space. Linked to the higher process gas pressure, the achievable mass flow rate of a vacuum pump increases and, thus, also the achievable mass flow rate of a process (that limits the deposition rate) increases. At a given mass flow rate of a process, pumps with lower pumping capacity may be used at higher pressures, or higher mass flow rates and thus higher deposition rates may be achieved using pumps having given pumping capacity. The problem of high system costs may thus be reduced.

A homogeneous layer deposition may be achieved. The homogeneity may be achieved with regard to the deposition rate and/or the layer properties in the longitudinal direction of the ICP source. This allows for the treatment of broader substrates or a simultaneous treatment of a higher number of smaller substrates. Costs for the system may thus be reduced and/or the throughput may be increased.

The maintenance effort may be reduced due to suppression of parasitic coatings on process gas outlet openings and a high deposition rate on the substrate. Problems occurring due to intensive maintenance work that are characteristic for PECVD are reduced.

Process-specific reactive gas control is facilitated. This is in particular advantageous for AlOx processes. Process-specific reactive gas control mechanisms allow the reactivity of the excited process gas to be reduced as required. The coupled plasma power should not be lowered below the limit necessary to maintain the H-mode when trying to achieve a low reactivity of the excited reactive gas. The dominant process of energy coupling remains electromagnetic induction. Due to the constant electric current in the inductor loop, homogeneous plasma conditions may be obtained in the longitudinal direction of the source.

The problem of an excessively high reactivity of the reactive gas, which increases parasitic deposition in the ICP source and thus reduces the deposition rate, may thus also be mitigated.

The ICP source is scalable in the longitudinal direction of the source. Source lengths of more than 1,000 mm, in particular more than 1,400 mm may be realized while still maintaining good homogeneity of the treatment. This allows larger coating widths while maintaining homogeneity. The throughput of the coating system may be increased, and/or the number of sources may be reduced at a given throughput.

The confinement of the process space from the reactive gas inlet at the gas supply tube 141 to the precursor inlet at the opening 159 encloses the inductors 130, 130a-c transverse to the longitudinal direction of the ICP source, thus confining the plasma space. Due to the arrangement of the inductors 130a, 130b along the center plane 160 of the ICP source, the gas directing arrangement 150 may be made narrow in comparison to a parallel inductor loop arrangement. The plasma volume is reduced, thus increasing the plasma density and thereby the plasma conductance at a given energy coupling rate. A discharge in the H-mode can thus take place even at higher pressures.

Furthermore, a configuration of the gas directing arrangement 150 that is narrow transverse to the longitudinal direction of the ICP source leads to an increase in the average gas velocity in the direction of the substrate at a given mass flow rate of the reactive gas. A diffusion-driven transport of the precursor gas from the respective gas inlets near the substrate plane toward the at least one inductor is reduced. The shield 158 surrounding the gas outlet openings in the additional gas tubes 142 for the precursor gas prevents excited reactive gas from diffusing into the interior of the shield 158. Parasitic coatings in this area are avoided, thus reducing the risk of occlusion of the gas outlet openings in the additional gas tubes 142.

The gas outlet slit 159 or the openings 159 of shield 158 may be located close to the substrate without creating inhomogeneity of deposition in the longitudinal direction of the ICP source 120. Any concentration gradients along the additional gas tube 142 are homogenized within the shield 158 so that a homogeneous flow density of the exiting precursor gas may be generated at the gas outlet slit 159 or the openings 159 in the longitudinal direction of the ICP source 120.

The ICP source 120 may be used both for dynamic and for static coating systems, but also for other treatment systems.

1. A treatment system, comprising:
a process chamber for treating at least one substrate, and
an inductively coupled plasma source, ICP source, having a longitudinal direction, wherein the ICP source comprises:
at least one inductor extending along the longitudinal direction of the ICP source,
a gas supply device for one or a plurality of process gases having at least one outlet opening that is configured to supply the process gas(es) along the longitudinal direction of the ICP source, and
a gas directing arrangement disposed in the process chamber said gas directing arrangement extending along the longitudinal direction of the ICP source and partially surrounding the at least one inductor.

2. The treatment system according to claim 1, wherein the gas directing device comprises a gas hood overlapping the at least one inductor and the at least one outlet opening of the gas supply device.

3. The treatment system according to claim 3, wherein the gas hood comprises an outlet whose width B₁ perpendicular to the longitudinal direction of the ICP source is at most 300 mm, in particular at most 200 mm, in particular at most 150 mm, in particular at most 130 mm.

4. The treatment system according to claim 3, wherein the gas hood has a further width B₂ perpendicular to the longitudinal direction of the ICP source on its upper side that is remote from the outlet, said further width B₂ being smaller than the width B₁ of the outlet.

5. The treatment system according to claim 2, wherein the gas hood has an inner width decreasing along the height direction of the gas hood.

6. The treatment system according to claim 2, wherein the gas directing arrangement has a height H in a center plane of the gas directing arrangement and an outlet with a width B₁ perpendicular to the longitudinal direction of the ICP source, wherein a ratio of width B₁ of the outlet to the height H of the gas directing arrangement B₁/H, is less than 1.0, in particular less than 0.7, in particular less than 0.6, in particular less than 0.5.

7. The treatment system according to claim 2, wherein the gas supply device comprises at least one gas supply tube extending parallel to the at least one inductor in the gas hood along the longitudinal length of the ICP source.

8. The treatment system according to claim 1, wherein the outlet opening of the gas supply device and the at least one inductor are spaced from each other along a center plane of the gas supply device, wherein preferably the outlet opening of a gas supply tube is positioned above the at least one inductor.

9. The treatment system according to claim 1, wherein the at least one inductor comprises a first inductor and a second inductor.

10. The treatment system according to claim 9, wherein the first inductor is electrically connected in series with the second inductor or in parallel with the second inductor.

11. (canceled)

12. The treatment system according to claim 9, wherein the first inductor and the second inductor are disposed in a center plane of the gas directing arrangement.

13. The treatment system according to claim 1, wherein the ICP source comprises a generator which is coupled with the at least one inductor or is configured to operate the ICP source in H-mode or comprises a HF or RF generator.

14-15. (canceled)

16. The treatment system according to claim 13, wherein the generator is configured to generate electric waves having wavelengths of at least 5 m, preferably of at least 10 m in the at least one inductor.

17. The treatment system according to claim 1, wherein the ICP source is configured to create plasma having an electron density of at least 10¹⁶/m³, preferably of at least 10¹⁷/m³.

18. The treatment system according to claim 1, wherein the ICP source is configured for operating at a pressure present in the process chamber within a range of 0.1 to 1000 Pa, in particular of 0.1 to 500 Pa, in particular of 0.1 to 250 Pa, in particular of 0.1 Pa to 200 Pa, in particular of 1 Pa to 100 Pa, in particular of 10 Pa to 100 Pa.

19. The treatment system according to claim 1, further comprising a gas distributor for at least one process gas, wherein the gas directing arrangement comprises a shield for the gas distributor.

20. The treatment system according to claim 19, wherein the shield comprises an outlet slit extending in the longitudinal direction of the ICP source along the gas directing arrangement, or a series of apertures arranged along the longitudinal direction of the ICP source.

21. The treatment system according to claim 20, wherein the outlet slit or the apertures have a width of at most 40 mm, in particular of at most 25 mm, in particular of at most 10 mm.

22. The treatment system according to claim 19, wherein the gas distributor comprises a plurality of outlet openings having an outlet opening diameter, wherein a ratio of the outlet opening diameter to a diameter of the gas distributor is at most 0.5, in particular at most 0.1.

23. The treatment system according to claim 1, wherein the gas directing arrangement is configured to suppress parasitic coating processes in the process chamber.

24. The treatment system according to claim 1, wherein the at least one inductor has a length of at least 1,000 mm, in particular of at least 1,200 mm, in particular of at least 1,400 mm along the longitudinal direction of the ICP source.

25. The treatment system according to claim 1, wherein the at least one inductor has an impedance that is variable along the longitudinal direction of the ICP source.

26. The treatment system according to claim 25, wherein the at least one inductor comprises a stepped inner conductor which has a conductor tube radius that varies along the longitudinal direction of the ICP source, and/or an insulation thickness that varies along the longitudinal direction of the ICP source.

27. The treatment system according to claim 1, wherein the treatment system is a continuous treatment system for dynamic treatment of substrates or is a batch system for static treatment of substrates.

28. (canceled)

29. The treatment system according to claim 1, wherein the treatment system is configured to perform one or more of the following:
i) perform a coating process,
ii) perform a chemical or physical etching process,
iii) oxidize a surface of the at least one substrate,
iv) generate oxides, nitrides, and/or oxynitrides,
v) functionalize surfaces, or
vi) perform a cleaning process.

30-34. (canceled)

35. A plasma treatment method for treating substrates using a treatment system, comprising the steps of:
positioning at least one substrate in a process chamber of the treatment system,
exciting an inductively coupled plasma, ICP, using an ICP source comprising at least one inductor extending along the longitudinal direction of the ICP source, a gas supply device and a gas directing arrangement disposed in the process chamber, said gas directing arrangement extending along a longitudinal direction of the ICP source and partially surrounding the at least one inductor, and
supplying a process gas or a plurality of process gases with the gas supply device at a plurality of positions along the longitudinal direction of the ICP source.

36. (canceled)

37. The plasma treatment method according to claim 35, wherein dynamic layer deposition takes place at a rate which
is at least 70 nm·m/min for depositing SiNx, or
is at least 8 nm·m/min for depositing AlOx.

38. The plasmas treatment method according to claim 35, wherein layer deposition takes place with a deviation of less than ±3%, in particular less than ±2% along the longitudinal direction of the ICP source.
